(19) United States
(12) Patent Application Publication
(10) Pub. No.: US 2007/0040098 A1
(43) Pub. Date: Feb. 22, 2007

(54) BINOCULAR TELESCOPE

(76) Inventor: KAZUYOSHI IMAZEKI, Tokyo (JP)

Correspondence Address: TREXLER, BUSHNELL, GIANGIORGI,;BLACKSTONE & MARR, LTD., 105 WEST ADAMS STREET, SUITE 3600, CHICAGO, IL, 60603, US

(21) Appl. No.: 11/419,683

(22) Filed: May 22, 2006

(30) Foreign Application Priority Data
Aug. 17, 2005 (JP) JP 2005-236722

(51) Int. Cl. H01L 27/00

(52) U.S. Cl. 250/208.1

(57) ABSTRACT

A binocular telescope includes a first CCD array and a first LCD array both disposed within one lens barrel, a second CCD array and a second LCD array both disposed within the other lens barrel, first and second CCD drive units and first and second LCD drive units disposed within a mount for the two lens barrels, externally-operable first and second selector switches, and an interface connected to a portable television tuner. The first and second selector switches are operated in such a manner that when moving contacts of the first and second selector switches are respectively switched to one fixed contacts, images focused onto the first and second CCD arrays are respectively formed on the first and second LCD arrays as images, and when their moving contacts are respectively switched to the other fixed contacts, images sent from the portable television tuner are formed on the first and second LCD arrays respectively.

### RELATED/PRIORITY APPLICATION

This application claims priority with respect to Japanese Application No. 2005-236722, filed Aug. 17, 2005.

### BACKGROUND OF THE INVENTION

1. Field of The Invention

The present invention relates to a binocular telescope wherein optoelectronic transducing elements are respectively disposed inside one and other lens barrels of the binocular telescope and control driving elements for the optoelectronic transducing elements are respectively disposed inside a mount for the one and other lens barrels, and scenes or sights ahead of the binocular telescope or images given from remote locations can selectively be seen in a state in which the binoculars are held to the eyes.

2. Description of the Related Art

There is generally provided a spectator stand at a homestretch section of a race course in a race car site. When the audience is watching an auto race at the seats or spectator stand, the audience is able to watch the state of the auto race at the homestretch section in front of the spectator stand relatively well. Since, however, an orbit racing course in the race car site is a long distance that extends for a few kilometers over its overall length, the state of the auto race at each location away from the spectator stand is often difficult to see because the location is far distant from the spectator stand. Therefore, television cameras which show up or display the state of the auto race are provided at their corresponding locations in the orbit racing course at the race car site. Images taken by the television cameras are projected onto a large screen placed in the race car site and at the same time the actual conditions of the auto race are to be broadcasted by relay. While on the contrary, all the spectators are not able to know about the state of the auto race in detail because the images projected onto the large screen cannot be well viewed even from any seat in the spectator stand.

Therefore, the audience who watches the auto race carries a binocular telescope and a portable television and watches it if the audience wants to know about the state of the auto race in detail. It has frequently been practiced to use the binocular telescope when the state of a nearby auto race is seen or observed and make good use of images projected onto the portable television when on the other hand, the state of a distant auto race is viewed. Even in this case, when the auto race is done over a long period of time, racing cars inevitably run in a state of being scattered here and there in the orbit racing course. Therefore, the audience attempts to, in association with changes in the conditions or circumstances of the auto race while hearing the public address, or radio calls or messages between each racing car and its corresponding pit, see images projected onto the large screen in good sight of the large screen, or look through the carried binocular telescope, or watch the display screen of the portable television carried in the same manner to thereby select the optimum means associated with the respective conditions and try to grasp the conditions of the auto race.

Thus, when the spectators who watch the auto race want to know about the conditions of the currently-executed auto race in detail, the spectators attempt to, in association with the changes in the conditions of the auto race, see the images on the large screen, or look through the carried binocular telescope, or see the display screen of the carried portable television, or hear the public address or the radio messages between each racing car and its corresponding pit. The spectators who have heretofore watched the auto race used to watch the auto race over a long period of time under their very busy states.

### SUMMARY OF THE INVENTION

The present invention has been made in view of such conditions. An object of the present invention is to provide a binocular telescope capable of selecting viewing of a nearby forward sight or scene or viewing of images on a portable television by merely using the binocular telescope with being held to the eyes.

In order to attain the above object, there is provided a binocular telescope equipped with means comprising:

a first CCD (Charged Coupled Device) array for imaging a forward scene, which is disposed inside one lens barrel and a first LCD (Liquid Crystal Display) array for displaying an image;

a second CCD array for imaging a forward scene, which is disposed inside the other lens barrel and a second LCD array for displaying an image;

first and second CCD drive units and first and second LCD drive units respectively disposed inside a mount for the one and other lens barrels;

first and second one-circuit two-contact switches individually switchable by external operations; and

an interface connectable to a portable television tuner,

wherein the first one-circuit two-contact switch has a moving contact connected to the first LCD array through the first LCD drive unit, one fixed contact connected to the first CCD array through the first CCD drive unit and the other fixed contact connected to the interface, respectively, and

wherein the second one-circuit two-contact switch has a moving contact connected to the second LCD array through the second LCD drive unit, one fixed contact connected to the second CCD array through the second CCD drive unit and the other fixed contact connected to the interface, respectively.

In the above means, the binocular telescope according to the present invention is equipped with first additive means wherein first and second memories are further disposed inside the mount for the one and other lens barrels and wherein the first memory is coupled to the first LCD drive unit and the second memory is coupled to the second LCD drive unit.

Further, in the above means, the binocular telescope according to the present invention is equipped with second additive means wherein in the mount for the one and other lens barrels, a connector capable of receiving a plug placed at a termination of a video signal line led out from the portable television tuner is disposed in a state of being exposed onto a mount surface, and the connector is conductively connected to the interface inside the mount.

As described above, the binocular telescope of the present invention, having the above means brings about advantageous effects in that when the moving contacts of the first and second one-circuit two-contact switches are respectively switched to one fixed contacts simultaneously, nearby forward scenes, i.e., the conditions of racing cars engaged in race in the vicinity can be seen through both eyes of a user, whereas when the moving contacts are switched to the other fixed contacts simultaneously, display images derived from the portable television, i.e., the conditions of racing cars engaged in race in the distance can be seen through both eyes of the user, and further, when one moving contact of the first and second one-circuit two-contact switches is switched to its corresponding one fixed contact and the other moving contact of the first and second one-circuit two-contact switches is switched to its corresponding other fixed contact, a nearby forward scene can be seen through one of both eyes of the user and a display image derived from the portable television can be seen through the other of both eyes thereof, whereby the user is able to immediately select viewing of the forward scenes, viewing of the television's display images and viewing of the forward scene and the television's display image together in a state in which the user holds the binocular telescope to the eyes, thus making it possible to cause the audience watching an auto race to sufficiently grasp the conditions of the auto race without taking as much busyness as the user used to.

Other features and advantages of the present invention will become apparent upon a reading of the attached specification.

### BRIEF DESCRIPTION OF THE DRAWINGS

The organization and manner of the structure and operation of the invention, together with further objects and advantages thereof, may best be understood by reference to the following description, taken in connection with the accompanying drawings, wherein like reference numerals identify like elements in which:

FIG. 1 relates to an embodiment of a binocular telescope of the present invention and is a transverse sectional view showing a configuration of its essential part.

### DETAILED DESCRIPTION OF THE INVENTION

A preferred embodiment of the present invention will be explained hereinafter with reference to the accompanying drawing.

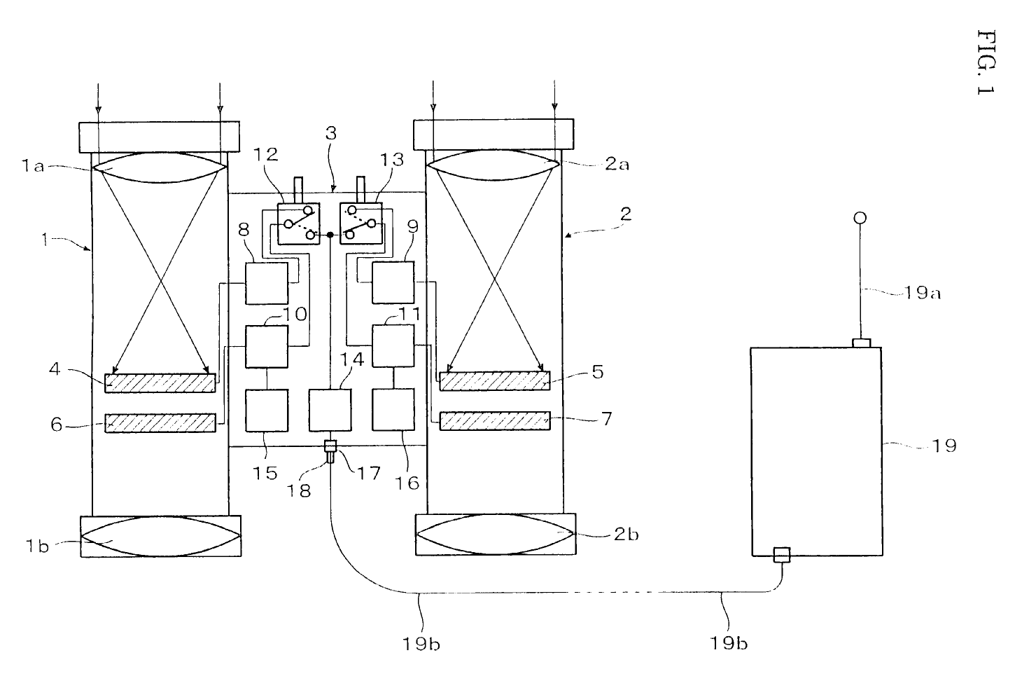

FIG. 1 relates to an embodiment of a binocular telescope of the present invention and is a transverse sectional view showing a configuration of its essential part.

As shown in FIG. 1, the binocular telescope according to the present embodiment is carried to a race car site or motordrome by an audience together with a portable television 19 to be described later when it is desired to watch an auto race, for example. A main body portion of the binocular telescope is formed of one lens barrel 1, the other lens barrel 2 and a mount 3 which is placed between the one and other lens barrels 1 and 2 and couples and holds the two lens barrels 1 and 2. In this case, the one lens barrel 1 includes an objective lens 1a placed inside a tip or leading end area into which external light is launched, an eye lens 1b placed inside a rear end area on the opposite side thereof, and a first CCD array 4 and a first LCD array 6 disposed inside an intermediate area defined therebetween. Similarly, the other lens barrel 2 includes an objective lens 2a disposed inside a tip or leading end area into which external light is launched, an eye lens 2b disposed inside a rear end area on the opposite side thereof, and a second CCD array 5 and a second LCD array 7 placed inside their intermediate area.

The mount 3 comprises a first CCD drive unit 8 and a second CCD drive unit 9, a first LCD drive unit 10 and a second LCD drive unit 11, a first one-circuit two-contact switch 12 and a second one-circuit two-contact switch 13, an interface 14, and a first memory 15 and a second memory 16 respectively disposed thereinside. Further, the mount 3 is provided with a connector 17 which allows a plug 18 to be described later to be fit into its casing surface. The mount 3 is provided with a first switch control part 12a which selects a moving contact of the first one-circuit two-contact switch 12, and a second switch control part 13a which selects a moving contact of the second one-circuit two-contact switch 13 both of which are disposed so as to lead out outward through the casing surface.

Besides, the portable television 19 carried by the audience who watches an auto race includes a receiving antenna 19a and a lead wire 19b connected thereto. Upon its use, the plug 18 connected to and disposed at the tip of the lead wire 19b is connected to its corresponding connector 17 of the mount 3 employed in the binocular telescope. In this case, the portable television 19 receives a television wave being propagated to within the race car site. The contents of the television wave represent the circumstances or conditions of auto racing photographed by television cameras disposed in respective locations of an orbit racing course in the race car site. A television signal received by the portable television 19 is subjected to predetermined processing thereinside, followed by being transmitted to the binocular telescope through the lead wire 19b as a video signal.

In the one lens barrel 1 and the other lens barrel 2, the first CCD array 4 and the second CCD array 5 are respectively placed in areas near the leading end areas in the internal intermediate areas. Similarly, the first LCD array 6 and the second LCD array 7 are placed in their corresponding areas near the rear end areas in the internal intermediate areas. The first CCD array 4 is connected to an input terminal of the first CCD drive unit 8 lying inside the mount 3, whereas the second CCD array 5 is connected to an input terminal of the second COD drive unit 9 lying inside the mount 3. The first LCD array 6 is connected to an output terminal of the first LCD drive unit 10 lying inside the mount 3, whereas the second LCD array 7 is connected to an output terminal of the second LCD drive unit 11 lying inside the mount 3.

Inside the mount 3, the first one-circuit two-contact switch 12 has the moving contact connected to an input terminal of the first LCD drive unit 10, one fixed contact connected to an output terminal of the first CCD drive unit 8, and the other fixed contact connected to an output terminal of the interface 14. The second one-circuit two-contact switch 13 has the moving contact connected to an input terminal of the second LCD drive unit 11, one fixed contact connected to an output terminal of the second CCD drive unit 9, and the other fixed contact connected to the output terminal of the interface 14. The first LCD drive unit 10 is selectively connected to the first memory 15, and the second LCD drive unit 11 is selectively connected to the second memory 16. The interface 14 has an input terminal connected to its corresponding terminal of the connector 17.

The operation of the binocular telescope according to the present invention based on the above configuration is as follows:

When nearby forward scenes or sights are seen through both eyes by means of the binocular telescope, the first switch control part 12a and the second switch control cart 13a are externally operated to switch the moving contact of the first one-circuit two-contact switch 12 and the moving contact of the second one-circuit two-contact switch 13 to one fixed contacts respectively. When, at this time, the focal points of the binocular telescope are adjusted to allow the forward scenes incident onto one lens barrel 1 and the other lens barrel 2 to be formed or focused on the first CCD array 4 and the second CCD array 5, their focused or image-formed states are read as electric signals at the first CCD drive unit 8 and the second CCD drive unit 9. The read electric signals are supplied to their corresponding first LCD drive unit 10 and second LCD drive unit 11 through the first one-circuit two-contact switch 12 and the second one-circuit two-contact switch 13. Then, images substantially identical to the above focused images are formed on the first LCD array 6 and the second LCD array 7, based on the outputs of the first LCD drive unit 10 and the second LCD drive unit 11. It is therefore possible to observe or see the nearby forward scenes through the binocular telescope by seeing these images through both eyes.

On the other hand, when the states of remote locations are seen through both eyes using the bioncular telescope, the first switch control part 12a and the second switch control part 13a are externally operated to switch the moving contact of the first one-circuit two-contact switch 12 and the moving contact of the second one-circuit two-contact switch 13 to the other fixed contacts respectively. At this time, video signals received by the portable television 19 are supplied via the plug 18 and the connectcor 17 from the lead wire 19b to the inside of the mount 3, where the video signals pass through the interface 14 and are respectively supplied to the first LCD drive unit 10 and the second LCD drive unit 11 via the first one-circuit two-contact switch 12 and the second one-circuit two-contact switch 13. Subsequent operations are the same as the above operations and hence images substantially identical to images based on the video signals are formed on the first LCD array 6 and the second LCD array 7, based on the outputs of the first LCD drive unit 10 and the second LCD drive unit 11. It is therefore possible to see the states or conditions of remote locations photographed by the television cameras via the binocular telescope by seeing these images through both eyes.

When a nearby forward scene is seen through one of both eyes and at the same time the state of a remote location is seen through the other thereof by using the binocular telescope, the first switch control part 12a and the second switch control part 13a are externally operated to switch the moving contact of one of the first one-circuit two-contact switch 12 and the second one-circuit two-contact switch 13, e.g., the switch 12 to the one fixed contact side and switch the moving contact of the other of the first one-circuit two-contact switch 12 and the second one-circuit two-contact switch 13, e.g., the switch 13 to the other fixed contact side. When, at this time, the focal points of the binocular telescope are adjusted to allow the forward scene incident onto one lens barrel 1 to be image-formed or focused on the first CCD array 4, its focused state is read as electric signals at the first CCD drive unit 8. The read electric signals are respectively supplied to the first LCD drive unit 10 through the first one-circuit two-contact switch 12, and an image substantially identical to the focused image is formed on the first LCD array 6 based on the output of the first LCD drive unit 10. It is therefore possible to see the nearby forward scene via the binocular telescope by seeing this image through one of both eyes. When a vide signal received by the portable television 19 is supplied to the inside of the mount 3 simultaneously with it, the video signal passes through the interface 14 and is supplied to the second LCD drive unit 11 through the second one-circuit two-contact switch 13, and hence an image substantially identical to an image based on the video signal is formed on the second LCD array 7 based on the output of the second LCD drive unit 11. It is therefore possible to observe or see the circumstances or conditions of the remote location photographed by each television camera by seeing this image through the other of both eyes.

Incidentally, while the above embodiment has shown the example in which the moving contact of the first one-circuit two-contact switch 12 is switched to the one fixed contact side, and the moving contact of the second one-circuit two-contact switch 13 is switched to the other fixed contact side, the eyes that watch the nearby forward scene and the circumstances of the remote location are respectively merely opposite to each other even though the moving contact of the first one-circuit two-contact switch 12 is switched to the other fixed contact side, and the moving contact of the second one-circuit two-contact switch 13 is switched to the one fixed contact side. Hence the operation of the binocular telescope remains unchanged.

Thus, according to the binocular telescope according to the present embodiment, the one lens barrel 1 and the other lens barrel 2 are made identical in configuration to each other, and the first switch control part 12a and the second switch control part 13a are externally operated to separately switch the first one-circuit two-contact switch 12 and the second one-circuit two-contact switch 13, thereby making it possible to see the images of the nearby forward scenes through both eyes, see the images photographed by the television cameras at the remote locations through both eyes and simultaneously see the image of the nearby forward scene through one of both eyes and the image photographed by each television camera at the remote location through the other thereof. When the nearby forward scene and the photographed contents of each television camera at the remote location are respectively seen through one of both eyes and the other thereof simultaneously, these both images have the contents different from each other. Therefore it is not possible to separately and always watch these images carefully in terms of visual mentality through the right and left eyes, respectively. Since, however, the images photographed by the television cameras are such ones that the scene of the currently shown-up or taken photographed images can be sufficiently understood from the broadcasted contents of voice together with the images, the audience in the race car site will be able to immediately determine which image should be observed carefully at any given time.

In the present embodiment, when the first CCD drive unit 8 and the second CCD drive unit 9 respectively convert the images focused on the first CCD array 4 and the second CCD array 5 to the electric signals, they convert the electric signal's to signals expressed in the format suitable for transmission/reception of the video signals, as one example MPEG-2-format signals. The so-obtained MPEG-2-format signals respectively drive the first LCD array 6 and the second LCD array 7 through the first LCD drive unit 10 and the second LCD drive unit 11, thereby allowing the images of the nearby forward scenes to be formed on the first LCD array 6 and the second LCD array 7.

If such a configuration that the first memory 15 and the second memory 16 can selectively be coupled to the first CD drive unit 10 and the second LCD drive unit 11 as shown in FIG. 1 is taken, it is then possible to selectively connect the first memory 15 and/or the second memory 16 to the first LCD drive unit 10 and/or the second LCD drive unit 11 when needed, allow the first memory 15 and/or the second memory 16 to record the images of the forward scenes or the photographed images of the television cameras, and form reproduced images of the recorded contents at the appropriate time.

While the preferred form of the present invention has been described, it is to be understood that modifications will be apparent to those skilled in the art without departing from the spirit of the invention. The scope of the invention is to be determined solely by the following claims.

What is claimed is:

1. A binocular telescope comprising:
a first CCD array for imaging a forward scene, which is disposed inside one lens barrel and a first LCD array for displaying an image;
a second CCD array for imaging a forward scene, which is disposed inside the other lens barrel and a second LCD array for displaying an image;
first and second CCD drive units and first and second LCD drive units respectively disposed inside a mount for the one and other lens barrels;
first and second one-circuit two-contact switches individually switchable by external operations; and
an interface connectable to a portable television tuner,
wherein the first one-circuit two-contact switch has a moving contact connected to the first LCD array through the first LCD drive unit, one fixed contact connected to the first CCD array through the first CCD drive unit and the other fixed contact connected to the interface, respectively, and
wherein the second one-circuit two-contact switch has a moving contact connected to the second LCD array through the second LCD drive unit, one fixed contact connected to the second CCD array through the second CCD drive unit and the other fixed contact connected to the interface, respectively.

2. The binocular telescope according to claim 1, further comprising first and second memories disposed inside the mount for the one and other lens barrels, wherein the first memory is connected to the first LCD drive unit and the second memory is connected to the second LCD drive unit.

3. The binocular telescope according to claim 1, wherein the mount for the one and other lens barrels is disposed in a state in which a connector capable of receiving a plug placed at a termination of a video signal line led out from the portable television tuner is being exposed onto a mount surface, and the connector is conductively connected to the interface inside the mount.
